(19) United States
(12) Patent Application Publication
(10) Pub. No.: US 2014/0103528 A1
(43) Pub. Date: Apr. 17, 2014

(54) SEMICONDUCTOR DEVICE

(71) Applicant: LAPIS SEMICONDUCTOR CO., LTD., YOKOHAMA-SHI (JP)

(72) Inventor: Yoshifumi Sakamoto, Tokyo (JP)

(21) Appl. No.: 14/140,842

(22) Filed: Dec. 26, 2013

Related U.S. Application Data
(63) Continuation of application No. 12/403,430, filed on Mar. 13, 2009.

(30) Foreign Application Priority Data
Apr. 22, 2008 (JP) 2008-111087

(51) Int. Cl. H01L 31/02; H01L 23/498

(52) U.S. Cl. CPC H01L 31/02005; H01L 23/49811
USPC 257/737

(57) ABSTRACT

A semiconductor device, that is approximately identical in package size to a semiconductor chip, such as a W-CSP, is devised to secure a wider area for sealing such as laser marking. A semiconductor substrate has a plurality of via electrodes extending from the bottom of the semiconductor substrate to top electrodes, a bottom wire net formed at the bottom of the semiconductor substrate such that the bottom wire net is connected to the via electrodes, and an insulative film covering the bottom wire net. A sealing area having a sealing mark is disposed at the bottom of the semiconductor substrate. The sealing area is located such that the outer circumference of the sealing area is spaced apart from the bottom wire net in a direction parallel to a sealing mark forming surface, and the outer circumference of the sealing area is disposed at the edge of the semiconductor substrate.

### CROSS-REFERENCE TO RELATED APPLICATION

This application is a continuation application of application Ser. No. 12/403,430 filed Mar. 13, 2009, which is hereby incorporated for all purposes.

### BACKGROUND OF THE INVENTION

1. Field of the Invention

The present invention relates to a semiconductor device, and, more particularly, to an image sensor having a wafer level chip size package (W-CSP) structure.

2. Description of the Related Art

The reduction in size, the increase in density, and the increase in function of recent information equipment represented by mobile phones with cameras and digital cameras are remarkably in progress. A wafer level chip size package (hereinafter, referred to as a ‘W-CSP’), i.e., a package of the same size as a chip, is known as a technology for achieving the reduction in size of an imaging device, such as a CCD or a CMOS, mounted in such equipment.

The W-CSP is a newly conceptual package the whole assembling process of which is completed in a wafer state. The W-CSP has an external structure in which terminals are arranged at the bottom of the package in a grid fashion in the same manner as a fine pitch ball grid array (FBGA). The package size is approximately equal to the chip size.

FIG. 1 is a sectional view illustrating the structure of an image sensor (solid state imaging device) 30 manufactured using a W-CSP technology. At the top of an image sensor chip 4, made of silicon, is formed a light receiving unit 3. The light receiving unit 3 includes photodiodes arranged in a matrix fashion and charge coupled devices (CCD). At the top of the light receiving unit 3 is stacked a micro lens array 3a. At the top of the image sensor chip 4 are formed bonding pads 9, which are electrically connected to the light receiving unit 3. To each bonding pad 9 is electrically connected a via electrode 10, which extends from the top to the bottom of the image sensor chip 4. Between each via electrode 10 and the image sensor chip 4 is disposed an insulation film 11 for achieving the insulation between each via electrode 10 and the image sensor chip 4. At the bottom of the image sensor chip 4 is formed an anti-reflection film 23. On the anti-reflection film 23 are formed bottom wires 13, which are connected to the respective via electrodes 10 through corresponding openings formed through the anti-reflection film 23. Solder bumps 12 are electrically connected to the respective bottom wires 13 at the bottom of the image sensor chip 4. Mounting the image sensor 30 on a mounting substrate is achieved by reflowing the solder bumps 12. Above the image sensor chip 4 is formed a cover glass 6 such that a gap is defined between the image sensor chip 4 and the cover glass 6. The gap above the image sensor chip 4 is defined by a spacer 5 formed in such a manner that the spacer 5 surrounds the outer circumference of the light receiving unit 3. The spacer 5 and the cover glass 6 are bonded to each other by a bonding agent 20.

When the image sensor is constructed in the W-CSP structure as described above, it is possible to reduce the size and weight of the device, and, in addition, to mount the device on a mounting substrate by batch reflow without adopting a high-priced individual mounting method using a flip chip bonder in a clean room.

See Japanese Patent Kokai No. 2007-184680 (Patent Literature 1) and Japanese Patent Kokai No. 2006-73852 (Patent Literature 2).

### SUMMARY OF THE INVENTION

Generally, at the time of manufacturing a semiconductor device, laser sealing is performed at the top or the bottom of the package such that a letter, a number, and a symbol, indicating the name, manufacturing date, manufacturing lot, and properties of a product are marked at the top or the bottom of the package. The sealing mark formed by the laser sealing is used as a recognition mark to prevent the mixture of another kind of a part at the time of mounting the semiconductor device on a mounting substrate or as a position recognition mark at the time when the semiconductor device is mounted by a mounter. Also, the sealing mark is used to trace the manufacturing history when the semiconductor is defected. In the W-CSP aiming at the reduction of the package size, however, a bad effect due to the laser sealing is considered.

That is, since the distance from the sealing surface to the top of the semiconductor chip is very small in the W-CSP, there is a possibility that bottom wires may be exposed by the forming of the sealing mark, or the bottom wires may be melted due to heat emitted from the laser, with the result that the insulation of the semiconductor device may be deteriorated. Also, it is not possible to form the sealing mark at a light receiving region in a device having a light receiving element, such as an image sensor. In a W-CSP, therefore, the region where it is possible to form the sealing mark by the laser sealing is very restricted due to the properties of the package, with the result that it is not easy to extract the sealing area.

Therefore, the present invention has been made in view of the above problems, and it is an object of the present invention to provide a semiconductor device, approximately identical in package size to a semiconductor chip, such as a W-CSP, wherein the semiconductor device is capable of securing a wider sealing area.

In accordance with the present invention, the above and other objects can be accomplished by the provision of a semiconductor device including a rectangular semiconductor substrate, a plurality of top electrodes formed at a top of the semiconductor substrate, a plurality of via holes formed in the semiconductor substrate such that the via holes extend from a bottom of the semiconductor substrate to the respective top electrodes, a conductor covering inner walls of the respective via holes, a bottom wire net disposed at the bottom of the semiconductor substrate such that the bottom wire net is connected to the conductor, an insulative film covering the bottom wire net, and a sealing area having a sealing mark formed on the insulative film, wherein the sealing area is located such that an outer circumference of the sealing area is spaced apart from the bottom wire net in a direction parallel to a sealing mark forming surface, and the outer circumference of the sealing area coincides with an outer circumference of the semiconductor substrate.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view illustrating the structure of an image sensor having a conventional W-CSP structure;

FIG. 2 is a sectional view illustrating the structure of an image sensor according to an embodiment of the present invention;

FIG. 3 is a sectional view illustrating the structure of an image sensor similar to an embodiment of the present invention;

FIG. 4 is a bottom view of the image sensor according to the an embodiment of the present invention;

FIGS. 5A to 5E are views illustrating various arrangements of sealing areas and various sizes of the sealing areas;

FIGS. 6A to 6I are sectional view illustrating a process for manufacturing the image sensor according to the an embodiment of the present invention;

FIG. 7 is a sectional view illustrating the structure of an image sensor according to another embodiment of the present invention;

FIG. 8A is a plan view illustrating a sealing area of the image sensor according to the another embodiment of the present invention; and

FIG. 8B is a sectional view taken along line 8B and 8B of FIG. 8A.

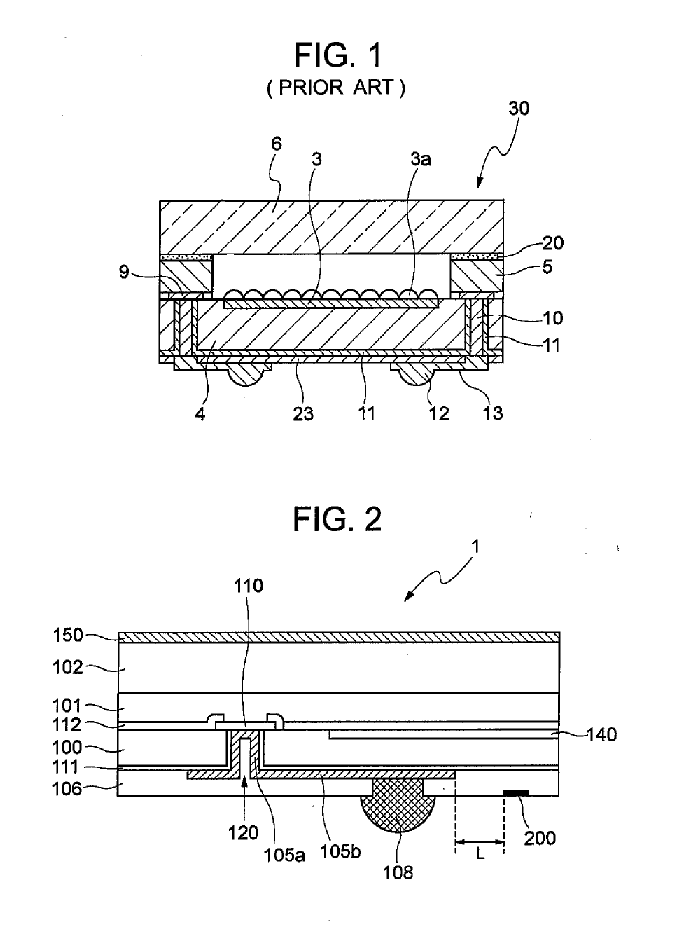

### DETAILED DESCRIPTION OF THE PREFERRED EMBODIMENTS

Now, preferred embodiments of the present invention will be described in detail with reference to the accompanying drawings. The same or similar elements are denoted by the same reference numerals even though they are depicted in different drawings.

### First Embodiment

FIG. 2 is a sectional view illustrating the structure of an image sensor 1 including a W-CSP structure according to a first embodiment of the present invention. A semiconductor substrate 100, made of a silicon single crystal, forms a main body of the image sensor 1. At the top of the semiconductor substrate 100 are formed light receiving elements 140, such as CMOS circuits or CCDs. A large number of the light receiving elements 140 corresponding to the number of pixels are formed on the semiconductor substrate 100. Light emitted from an imaging object is focused on light receiving surfaces of the respective light receiving elements 140 by an optical system, such as lenses, mounted at the outside. Each light receiving element 140 outputs a photoelectric conversion signal corresponding to the intensity of the received light as a detection output signal. As a result, image data are created from the positions and detection output signals of the respective light receiving elements.

A surface electrode 110 made of a metal, e.g., aluminum is formed on the surface of the semiconductor substrate 100, and the transmission/reception of a detection output signal and the input of a bias voltage are performed through the surface electrode. A passivation film 112 made of a polymide or the like, having an opening at a position where the surface electrode 110, is formed on the surface of the semiconductor substrate 100, so that the surface of the semiconductor substrate 100 is protected.

Through the semiconductor substrate 100 is formed a via hole 120, which extends from the bottom side of the semiconductor substrate 100 to a top electrode 110. The inner wall of the via hole 120 is covered with a conductive film, made of copper, which constitutes a via electrode 105a. The via electrode 105a is electrically connected to the top electrode 110 at the inner end of the via hole 120. A bottom wire 105b electrically connected to the via electrode 105a extends at the bottom side of the semiconductor substrate 100. The inner wall of the via hole 120 and the bottom of the semiconductor substrate 100 are covered with an insulative film 111, by which the via electrode 105a and the bottom wire 105b are insulated from the semiconductor substrate 100. The bottom of the semiconductor substrate 100 is covered with an insulative film 106, made of solder resist, which secures insulation at the bottom side of the semiconductor substrate 100. At the end of the bottom wire 105b is formed a solder bump 108, which extends through an opening formed through the insulative film 106. The solder bump 108 is electrically connected to the top electrode 110 via the bottom wire 105b and the via electrode 105a. Consequently, it is possible to draw a detection output signal from the bottom side of the semiconductor substrate 100 and to supply bias voltage. The solder bump 108 constitutes a joint to a mounting substrate on which the image sensor 1 is mounted.

On the semiconductor substrate 100 is formed an adhesive layer 101 exhibiting light transmission. Instead of forming the adhesive layer exhibiting light transmission, it is possible to provide a gap at a region corresponding to the adhesive layer. On the adhesive layer 101 is formed a glass substrate 102 exhibiting light transmission. To the top of the glass substrate 102 is adhered a protective film 150 for preventing the top of the glass substrate 102 from being scratched during the manufacture of the image sensor 1. The protective film 150 is provided only to protect the glass substrate 102, and therefore, the protective film 150 is separated from the image sensor 1 when the image sensor 1 is mounted on the mounting substrate.

At the bottom side of the image sensor 1, i.e., at the side of the image sensor 1 where the solder bump 108 is formed, is formed a sealing mark 200, including a letter, a number, and a symbol, indicating the name, manufacturing date, and characteristics of a product. The sealing mark 200 is formed on the insulative film 106, which covers the bottom of the image sensor 1 by a laser sealing method. The sealing mark 200 is formed by cutting a groove in a sealing mark forming surface using power of laser emitted from a laser sealing apparatus. Consequently, when laser sealing is performed on the bottom wire 105b, the groove of the sealing mark reaches the bottom wire 105b, for example, in a case in which the thickness of the insulative film 106 decreases due to a poor manufacturing process or in a case in which laser power of the laser sealing apparatus is high. As a result, the bottom wire 105b is exposed, and therefore, it is not possible to secure the insulation of the image sensor. For this reason, the sealing mark is not formed on the bottom wire.

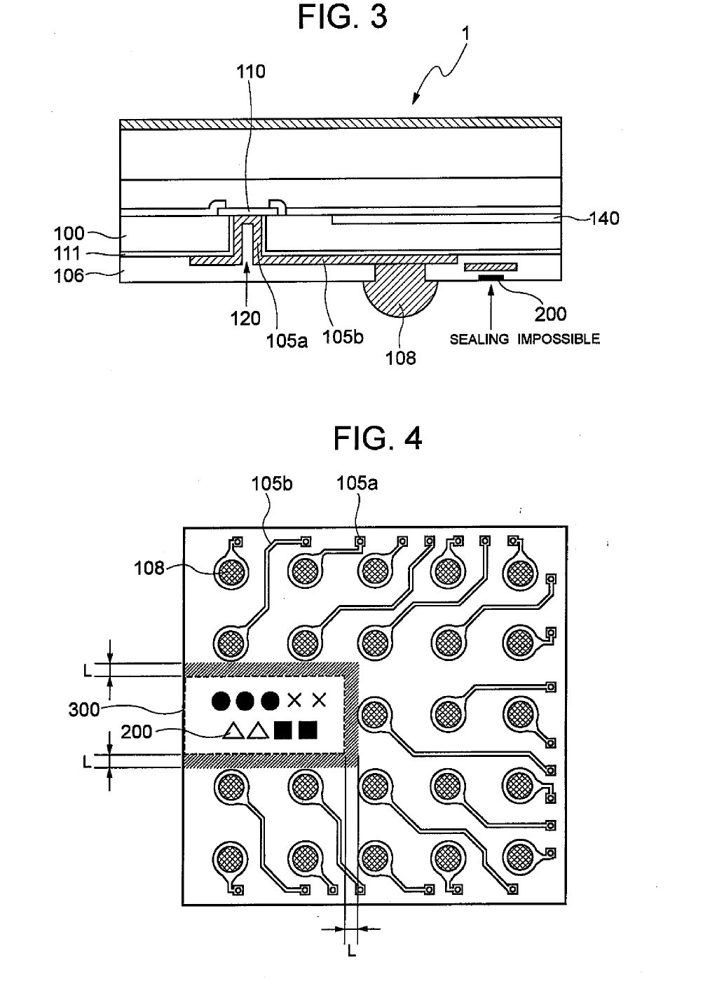

Also, it is necessary to consider the effect of heat due to the laser when performing the laser sealing, and therefore, it is necessary to secure not only the distance in the depth direction from the sealing mark forming surface to the bottom wire 105b but also the distance in the direction parallel to the sealing mark forming surface. In other words, the outer circumference of the sealing mark 200 is disposed at a position remote from the position where the bottom wire 105b and the solder bump 108 close to the sealing mark 200 are formed by at least a distance L in the direction parallel to the sealing mark forming surface. Furthermore, in a case in which the bottom wire 105b is constructed as a multi-layer structure as shown in FIG. 3, the sealing mark 200 can not be formed on insulative film 106 because adequate distance in the direction parallel to the sealing mark forming surface can not be realized between sealing mark 200 and the upper layer of bottom wire 105b.

FIG. 4 is a bottom view of the image sensor 1. The image sensor 1 is diced at the final step of the manufacturing process, with the result that, as shown in FIG. 4, the image sensor 1 is provided in the form of a chip-type image sensor. The bottom of the image sensor is covered with the insulative film 106, and a plurality of the solder bumps 108 are formed in the openings formed through the insulative film 106 such that the solder bumps 108 are arranged in a matrix fashion. Also, FIG. 4 shows the via electrodes 105a and the bottom wires 105b disposed at the lower layer of the insulative film 106. The via electrodes 105a are arranged along the edge of the divided image sensor 1. The bottom wires 105b are connected to the respective via electrodes 105a. Each bottom wire 105b extends to a position where the corresponding solder bump 108 is formed. Each solder bump 108 is connected to the end of the corresponding bottom wire 105b. The respective bottom wires 105b connected between the solder bumps 108 and the via electrodes 105a are formed in wiring patterns to secure an appropriate space between neighboring bottom wires 105b such that the neighboring bottom wires 105b are not adjacent to each other.

Since the plurality of solder bumps are disposed at the bottom of the image sensor 1, and the bottom wires are disposed at a position very close to the top of the image sensor 1, as described above, it is necessary to study the arrangement of the solder bumps and the extension of the bottom wires in order to secure a sealing area at the bottom side of the image sensor 1 while securing the required number of the solder bumps.

In this embodiment, a sealing area 300, surrounded by a broken line of FIG. 4, is provided at the bottom of the image sensor 1. In the sealing area 300 are formed the sealing mark 200, including a letter, a number, and a symbol, indicating the name, manufacturing date, and manufacturing lot of a product. In this embodiment, the size of the sealing mark 200 is estimated to be equal to or greater than the pitch of the solder bumps 108.

Since it is necessary that the outer circumference of the sealing area 300 be disposed at a position remote from the position where the bottom wire 105b and the solder bump 108 close to the sealing area 300 are formed by at least the distance L in the direction parallel to the sealing mark forming surface, such that the sealing area 300 is not disposed above the region where the bottom wires are formed as described above, and heat generated by the laser does not adversely affect the neighboring solder bumps and bottom wires, a region indicated by slant lines in the drawing is excluded from the sealing area. For example, the distance L is decided in consideration of the nonuniformity of the thickness of the insulative film 106 or the nonuniformity of the laser power of the laser sealing apparatus such that heat generated during the laser sealing does not affect the bottom wires and the solder bumps even when the nonuniformity of the thickness of the insulative film 106 or the nonuniformity of the laser power of the laser sealing apparatus is serious.

In a situation in which it is not easy to secure the sealing area as described above, the semiconductor device according to the present invention is constructed in a structure in which the sealing area 300 is disposed at the edge of the image sensor 1, as shown in FIG. 4, such that the size of the sealing area 300 is increased as large as possible. In other words, the sealing area is disposed such that the outer circumference of the sealing area coincides with the outer circumference of the divided image sensor chip. When the sealing area 300 is disposed at the edge of the image sensor chip, it is possible to increase the size of the sealing area as compared with a case in which the sealing area is disposed at the central part of the image sensor 1 without increasing the package size and reducing the solder bumps and the bottom wires.

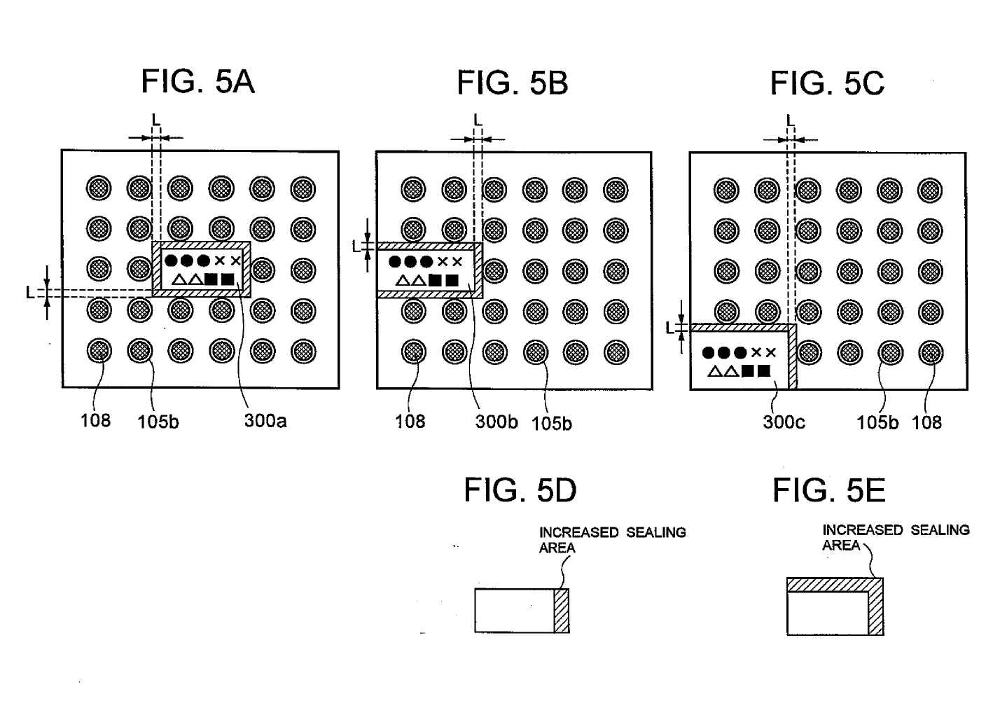

FIG. 5A illustrates a case in which a sealing area 300a is disposed at the central part of the bottom side of the image sensor 1. In this case, the sealing area 300a is surrounded by the solder bumps 108. Since it is necessary that the outer circumference of the sealing area 300a be disposed at a position remote from the position where the solder bumps 108 are formed by the distance L in the direction parallel to the sealing mark forming surface, as described above, a region indicated by slant lines in the drawing is excluded from the sealing area. That is, in a case in which the sealing area is disposed at the central part of the chip, it is necessary to retreat all four sides constituting the outer circumference of the sealing area from the position where the solder bumps 108 are formed by the distance L. As a result, it is not possible to secure a sufficient sealing space and to form a sealing mark including a predetermined number of letters, each of which has a predetermined size, in the sealing area 300a.

FIG. 5B illustrates a case in which a sealing area 300b is disposed at the edge of the image sensor 1. As shown in FIG. 5B, the sealing area 300b is disposed at the left end of the image sensor 1. In this case, no solder bumps and no bottom wires exist at the left side of the sealing area 300b. Consequently, it is not necessary to retreat the left end of the sealing area 300b by the distance L at, as in the case shown in FIG. 5A. As a result, it is possible to extend the left end of the sealing area 300b to the left end of the chip, and therefore, it is possible to increase the size of the sealing area 300b such that the size of the sealing area 300b is greater than that of the sealing area 300a shown in FIG. 5A.

FIG. 5D illustrates that the sealing area 300a and the sealing area 300b overlap with each other to compare the sizes of the sealing area 300a and the sealing area 300b. The shaded portion of FIG. 5D indicates the increased size of the sealing area. When the sealing area is disposed at the edge of the chip as described above, it is possible to increase the size of the sealing area without increasing the package size and reducing the solder bumps and the bottom wires. Also, the increased portion may be attached to the sealing area. Alternatively, the increased portion may be attached to the region where the solder bumps and the bottom wires are formed.

FIG. 5C illustrates a case in which a sealing area 300c is disposed at a corner of the chip. As shown in FIG. 5C, the sealing area 300c is disposed at the lower left corner of the image sensor 1. In this case, no solder bumps and no bottom wires exist at the left side and the lower side of the sealing area 300c. Consequently, it is not necessary to retreat the left end and the lower end of the sealing area 300c by the distance L, as in the case shown in FIG. 5A. As a result, it is possible to extend the left end and the lower end of the sealing area 300c to the left end and the lower end of the chip, and therefore, it is possible to increase the size of the sealing area 300c such that the size of the sealing area 300b is greater than that of the sealing area 300a shown in FIG. 5A. Also, in this case, it is possible to increase the size of the sealing area 300c such that the size of the sealing area 300b is greater than that of the sealing area 300b shown in FIG. 5B.

Also, FIG. 5E illustrates that the sealing area 300a and the sealing area 300c overlap with each other to compare the sizes of the sealing area 300a and the sealing area 300c. The shaded portion of FIG. 5E indicates the increased size of the sealing area. When the sealing area 300c is disposed at a corner of the chip, as described above, it is possible to further increase the size of the sealing area without increasing the package size and reducing the solder bumps and the bottom wires. The increased portion may be attached to the sealing area. Alternatively, the increased portion may be attached to the region where the solder bumps and the bottom wires are formed.

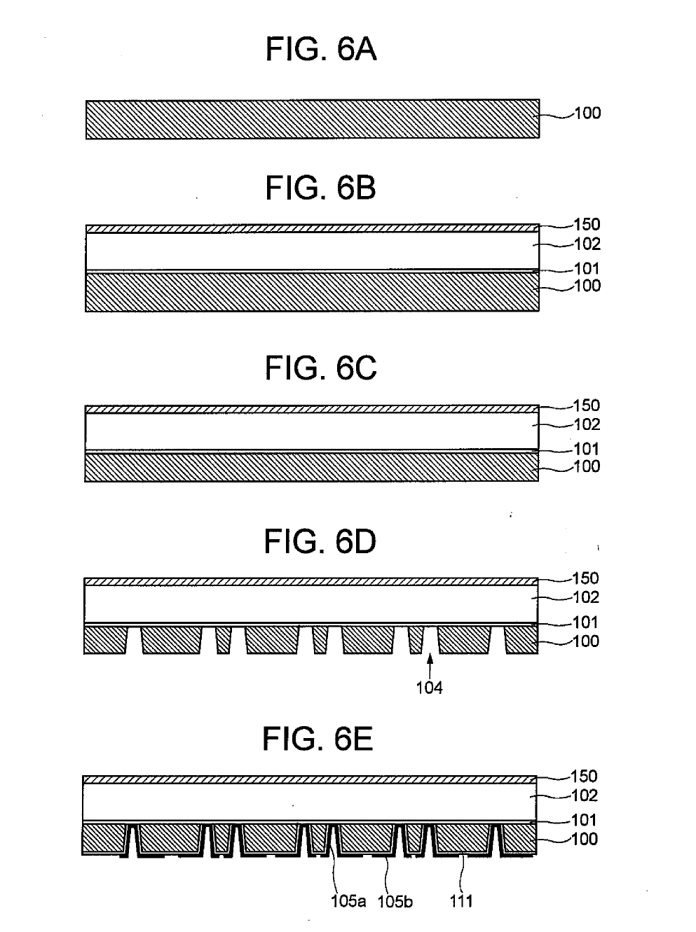

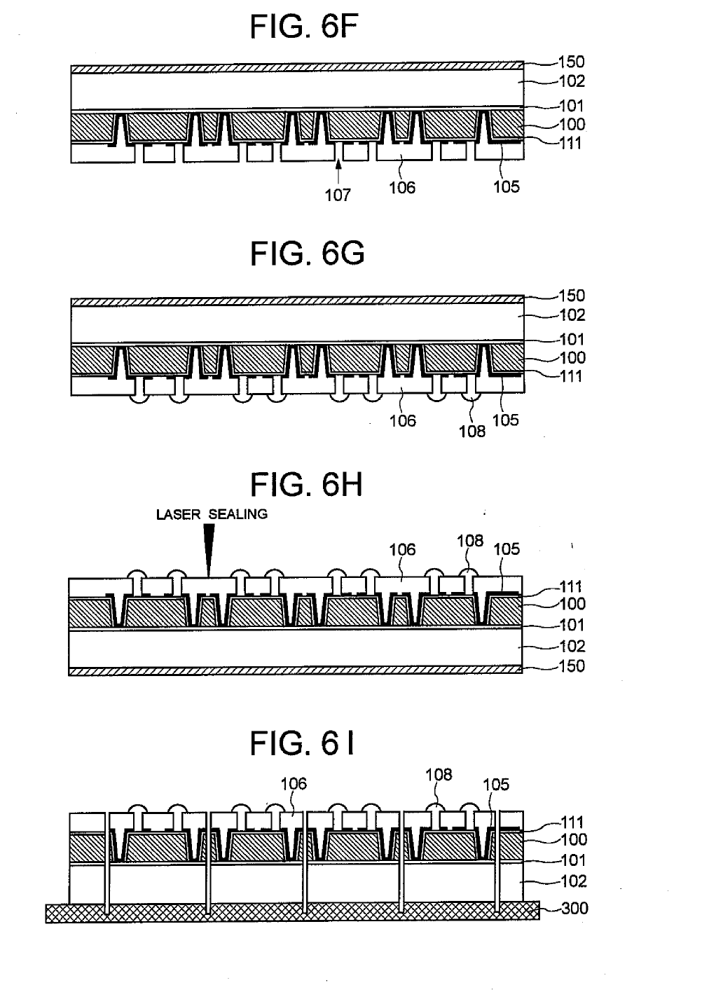

Hereinafter, a method of manufacturing the image sensor 1 with the above-stated construction will be described with reference to manufacturing process views shown in FIGS. 6A to 6I.

First, a semiconductor substrate 100, made of a silicon single crystal, having light receiving elements, such as CMOS circuits or CCDs, top electrodes, and other components necessary to manufacture the image sensor, is prepared (FIG. 6A).

On the other hand, a glass substrate 102 having a protective film 150 adhered to the top thereof is prepared. The protective film 150 is provided only to protect the glass substrate 102 such that the glass substrate 102 is prevented from being scratched during the manufacture of the image sensor. The protective film 150 is adhered to the top of the glass substrate 102 such that the protective film 150 covers the entire surface of the glass substrate 102. Subsequently, a transparent bonding agent 101 is applied to the light receiving element forming surface of the semiconductor substrate 100, and the semiconductor substrate 100 and the glass substrate 102 are attached to each other (FIG. 6B).

Subsequently, the bottom of the semiconductor substrate 100 is ground until the thickness of the semiconductor substrate 100 reaches a predetermined value (FIG. 6C).

Subsequently, a photo mask, having openings located at parts corresponding to positions where top electrodes (not shown) are formed, are formed at the bottom side of the semiconductor substrate 100, and then the semiconductor substrate 100 exposed through the openings of the photo mask is etched to form via holes 104 necessary to form via electrodes. The via holes 104 are etched until the via holes 104 reach the top electrodes (not shown) formed at the top of the semiconductor substrate 100 (FIG. 6D).

Subsequently, an insulative film 111, made of SiO₂, is deposited on the inner walls of the via holes 104 and the bottom of the semiconductor substrate 100 by a CVD method such that the inner walls of the via holes 104 and the bottom of the semiconductor substrate 100 are covered with the insulative film 111. After that, the insulative film 111 deposited at the inner ends of the via holes 104 is etched to expose the top electrodes (not shown) in the respective via holes 104. Subsequently, a barrier metal layer, made of TiN, and a plating sheet layer, made of copper (Cu), are sequentially deposited on the side walls and the inner ends of the via holes 104 and on the bottom of the semiconductor substrate 100 by the CVD method. After that, electrodes are attached to the plating sheet layer, and via electrodes 105a, made of copper (Cu), are formed at the inner walls of the via holes 104 by an electrolytic plating method. At the same time, bottom wires 105b are formed on the insulative film 111 located at the bottom of the semiconductor substrate 100. After that, the bottom wires 105b are patterned, by etching, to form a predetermined wire pattern. The via electrodes 105a are electrically connected to the top electrodes (not show) at the inner ends of the via holes 104 (FIG. 6E).

Subsequently, solder resist, made of a photo-curable epoxy resin, is applied to the entire bottom of the semiconductor substrate 100, on which the bottom wires 105b are formed, with a thickness of approximately 30 um, such that the entire bottom of the semiconductor substrate 100 is covered with the solder resist. After drying the solder resist, the exposed part of the solder resist is photo-cured through a predetermined photo mask. After that, the unexposed part of the solder resist is selectively removed to form an insulative film 106 having openings 107 formed at solder bump forming positions (FIG. 6F).

Subsequently, solder bumps 108 are formed by an electroplating method such that the solder bumps 108 are electrically connected to the top electrodes 105b exposed through the openings 107 of the insulative film 106 (FIG. 6G).

Subsequently, a sealing mark is formed on the insulative film 106 using a laser sealing apparatus before chip-type division. The sealing mark is formed in the sealing area 300 provided at the edge of the chip as shown in FIG. 4. The sealing depth by the laser sealing is administered as laser power. The sealing area 300 is located such that the outer circumference of the sealing area 300 is spaced apart by a predetermined distance L from the bottom wires 105b and the solder bumps 108 in the direction parallel to the sealing mark forming surface, in consideration of the nonuniformity of the laser power of the sealing apparatus and the nonuniformity of the insulative film 106 such that heat generated during the laser sealing does not affect the bottom wires and the solder bumps even when the nonuniformity of the laser power of the sealing apparatus or the nonuniformity of the insulative film 106 is serious (FIG. 6H).

Subsequently, the protective film 150 is separated from the glass substrate 102, the glass substrate 102 is adhered to a wafer tape 300, and division into chip-type image sensors 1 is performed by dicing (FIG. 6I). Consequently, the image sensor 1 according to the present invention is completed through the above-described processes.

### Second Embodiment

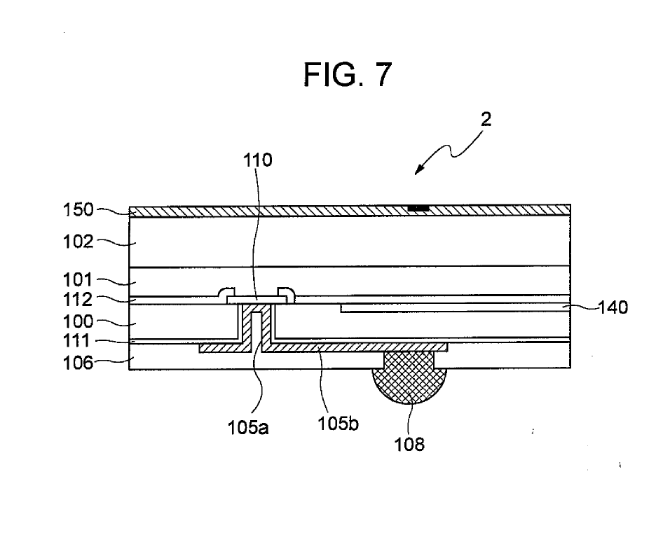

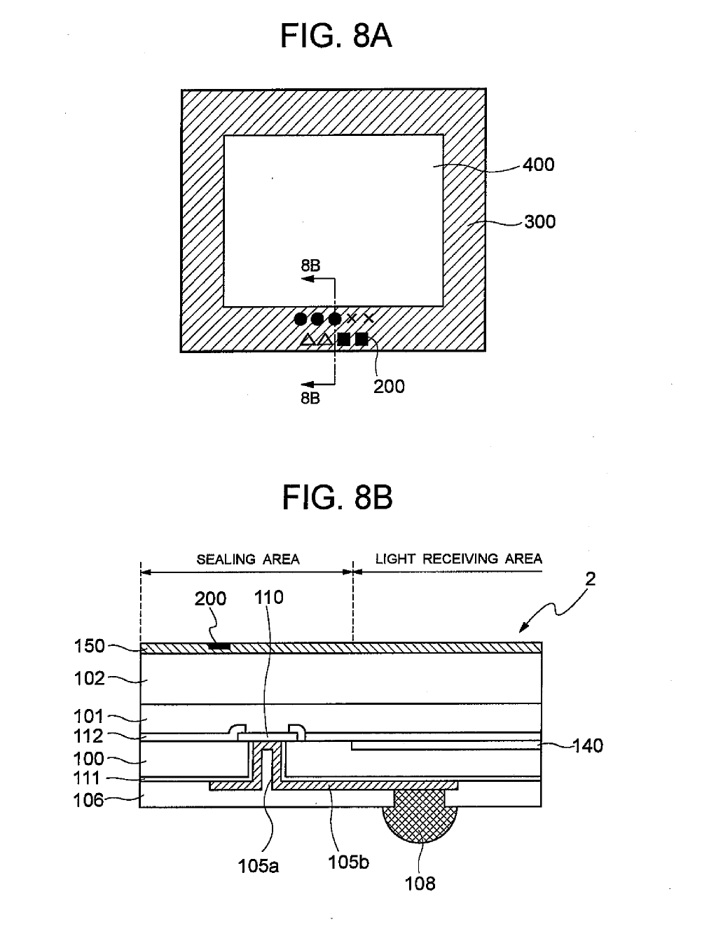

FIG. 7 is a sectional view illustrating the structure of an image sensor 2 having a W-CSP structure according to a second embodiment of the present invention. The image sensor 2 is different from the image sensor 1 according to the first embodiment in that the sealing mark 200 is not formed at the bottom side of the semiconductor substrate 100 but on the protective film 150 adhered to the glass substrate 102. That is, since the bottom wires, which are formed in such a manner that the bottom wires evade the sealing mark, do not exist directly below the protective film 150 of the image sensor 2, and the protective film 150 is removed before the image sensor is mounted on a mounting substrate, and therefore, it is possible to use the entire surface of the sealing mark as the sealing area, while the sealing mark does not disturb the reception of light during the use of the image sensor. Generally, the protective film 150 is removed prior to dicing. However, it is also possible to ship the image sensor in a wafer state or in a divided chip state while the protective film is adhered to the glass substrate. It is possible for a user to use the sealing mark 200 formed on the protective film 150 as a position recognition mark or a direction recognition mark, before removing the protective film 150, at the time of mounting the image sensor on a mounting substrate.

When scratches are formed at the glass substrate 102 right below the protective film 150 by laser sealing performed on the protective film 150, according to the property and the thickness of the protective film 150, the scratches act as disturbance, with the result that it may not be possible to obtain appropriate detection output signals from the light receiving elements. In this case, it is preferred to form the sealing mark such that the sealing mark evades a light receiving area 400 where light is received by the light receiving elements 140, for example, as shown in FIGS. 8A and 8B. FIG. 8A is a plan view of the image sensor 2, and FIG. 8B is a sectional view taken along line 8B and 8B of FIG. 8A. That is, the light receiving area 400 is disposed, for example, at the central part of the image sensor 2, and the outer circumferential region surrounding the light receiving area 400 is the sealing area 300. Consequently, it is possible to perform the sealing on the protective film, while not affecting its function as the image sensor, by disposing the sealing area 300 such that the sealing area 300 evades the light receiving area 400.

When the edge of the light receiving area is the sealing area 300, as described above, it is possible to form the sealing mark directly on the glass substrate 102. Even in this case, its function as the image sensor is not affected, and, the sealing mark may remain even after the image sensor is mounted on a mounting substrate.

Also, even when the sealing mark is formed at the bottom side of the image sensor as in the first embodiment, it is also possible to form the sealing mark on the protective film or the glass substrate as in this embodiment.

In the respective embodiments as described above, the application of the present invention to the image sensors was described as examples. However, the present invention is not limited to the image sensors, and therefore, the present invention may be applied to any device that has a function as a semiconductor device different from an image sensor.

This application is based on Japanese Patent Application No. 2008-111087 which is hereby incorporated by reference.

What is claimed is:

1. A chip size semiconductor device comprising:
a rectangular semiconductor substrate;
a plurality of top electrodes formed at a top of the semiconductor substrate;
a plurality of via holes formed in the semiconductor substrate such that the via holes extend from a bottom of the semiconductor substrate to the respective top electrodes;
a first insulative film formed on the bottom of the semiconductor substrate;
a conductor covering inner walls of the respective via holes;
a bottom wire net disposed at the bottom of the semiconductor substrate such that the bottom wire net is connected to the conductor;
a plurality of bumps formed on the bottom wire net; and
a second insulative film covering the bottom wire net and the first insulative film,
wherein the second insulative film has a sealing area that is a rectangular area having a first width and a second width, both of the first width and the second width are larger than a distance between neighboring ones of the bumps, and a sealing mark is formed in the sealing area.

2. The chip size semiconductor device of claim 1, wherein the sealing area has two sides neighboring at least the bumps.

3. The chip size semiconductor device of claim 1, wherein the sealing area is an area between at least two of the bumps.

4. The chip size semiconductor device of claim 1, wherein the sealing area has one side adjoining at least an edge of the chip size semiconductor device.

5. The chip size semiconductor device of claim 1, wherein the sealing area has two sides adjoining at least edges of the chip size semiconductor device.
